(19) United States
(12) Patent Application Publication
(10) Pub. No.: US 2010/0081233 A1
(43) Pub. Date: Apr. 1, 2010

(54) METHOD OF MANUFACTURING INTEGRATED CIRCUIT HAVING STACKED STRUCTURE AND THE INTEGRATED CIRCUIT

(75) Inventor: Byoung Su Lee, Jeolanam-do (KR)

Correspondence Address: Jae Y. Park, Kile, Goekjian, Reed & McManus, PLLC, 1200 New Hampshire Ave. NW, Suite 570, Washington, DC, 20036, US

(73) Assignee: Siliconfile Technologies Imc., Seoul (KR)

(21) Appl. No.: 12/516,364

(22) PCT Filed: Dec. 7, 2007
(86) PCT No.: PCT/KR07/06334

§ 371 Date: May 27, 2009

(30) Foreign Application Priority Data
Dec. 8, 2006 (KR) 10-2006-0124409

(51) Int. Cl. H01L 21/98

(52) U.S. Cl. 438/109; 438/637; 257/E21.705

(57) ABSTRACT

Provided are a method of manufacturing an integrated circuit having a stacked structure by forming a crystalline semiconductor thin film on a crystalline or amorphous substrate and the integrated circuit. Accordingly, the method of manufacturing the integrated circuit having the stacked structure uses a method of growing a crystalline semiconductor thin film on a polycrystalline or amorphous substrate, so that the method can be easily performed at low costs, and high-speed processing and high-density integration can be achieved.

### BACKGROUND OF THE INVENTION

1. Field of the Invention

The present invention relates to a method of manufacturing an integrated circuit having a stacked structure and the integrated circuit, and more particularly, to a method of manufacturing an integrated circuit having a stacked structure by using a crystalline semiconductor thin film forming technology and the integrated circuit having the stacked structure manufactured by using the method.

2. Description of the Related Art

Conventionally, in order to improve a performance of an integrated circuit, a method of reducing sizes of devices to improve a density and a processing speed, a method using semiconductor materials that achieve high speed response (for example, a method using strained Si instead of Si), and the like have been developed.

However, the method of reducing the sizes of the devices has problems in terms of an economic point of view in that a large investment to improve precision of lithography apparatuses is required, and manufacturing apparatus have to be replaced as new materials and a new manufacturing process are used.

In addition, the method using the semiconductor materials that achieve high speed response has problems in that there are difficulties in designing the integrated circuit due to electromagnetic interference (EMI) of adjacent devices as the devices are integrated at a high density and high-frequency regions are used.

Therefore, separately from the tendency toward decreases in sizes and increases in the speed of the devices, researches on three-dimensional stacking techniques of stacking a circuit layer defined on another plane on a circuit layer defined on a plane and electrically connecting the two layers to improve the performance and the density of the integrated circuit have been actively developed.

As methods associated with the three-dimensional stacking techniques, there are a multi-chip packaging method in packaging levels capable of integrating pads of wafers that are separately manufactured by using metal wires, and a wafer stacking method in device levels capable of individually connecting each device of wafers having circuits that are separately manufactured. Currently, the wafer stacking method of constructing integrated circuits in device levels includes an operation of forming a circuit on each wafer that is to be stacked and an operation of aligning and joining two wafers.

However, the joining method using the operation of aligning the wafers has problems in that forming a joining of more than two layers is difficult, releasing heat generated from each wafer is difficult, and a wafer thinning technique is needed since accurately aligning two wafers is difficult, so that practical uses of the method cannot be easily achieved.

### SUMMARY OF THE INVENTION

The present invention provides a method of manufacturing an integrated circuit having a stacked structure capable of forming a crystalline semiconductor thin film on a polycrystalline or amorphous substrate and the integrated circuit having the stacked structure.

The present invention provides a method of manufacturing an integrated circuit having a stacked structure on a crystalline substrate and the integrated circuit having the stacked structure.

According to an aspect of the present invention, there is provided a method of manufacturing an integrated circuit having a stacked structure, including steps of: (a) forming a first buffer layer and a first crystalline semiconductor layer on a first substrate; (b) forming a first circuit layer on the first crystalline semiconductor layer; (c) forming a second buffer layer and a second crystalline semiconductor layer on the first circuit layer; (d) forming a second circuit layer on the second crystalline semiconductor layer; and (e) electrically connecting the first and second circuit layers, wherein the first substrate is a substrate having an amorphous structure or a substrate having a polycrystalline structure, and each of the first and second buffer layers is constructed with a seed layer.

According to another aspect of the present invention, there is provided a method of manufacturing an integrated circuit having a stacked structure, including steps of: (a) forming a first circuit layer on a first crystalline semiconductor substrate; (b) forming a second buffer layer and a second crystalline semiconductor layer on the first circuit layer; (c) forming a second circuit layer on the second crystalline semiconductor layer; and (d) electrically connecting the first and second circuit layers.

### BRIEF DESCRIPTION OF THE DRAWINGS

The above and other features and advantages of the present invention will become more apparent by describing in detail exemplary embodiments thereof with reference to the attached drawings in which:

FIG. 1 is a flowchart of a method of manufacturing an integrated circuit having a stacked structure according to an embodiment of the present invention;

FIG. 2 is a view illustrating a manufacturing process according to the method illustrated in FIG. 1;

FIG. 3 is a view illustrating the integrated circuit having the stacked structure manufactured by using the method illustrated in FIG. 1;

FIG. 4 is a view illustrating a crystalline semiconductor thin film structure used as a substrate in the method of manufacturing the integrated circuit having the stacked structure according to the embodiment of the present invention;

FIG. 5 is a flowchart of a method of manufacturing an integrated circuit having a stacked structure according to another embodiment of the present invention;

FIG. 6 is a view illustrating a manufacturing process according to the method illustrated in FIG. 5; and

FIG. 7 is a view illustrating the integrated circuit having the stacked structure manufactured by using the method illustrated in FIG. 5.

### DETAILED DESCRIPTION OF THE INVENTION

Hereinafter, exemplary embodiments of the present invention will be described in detail with reference to the attached drawings.

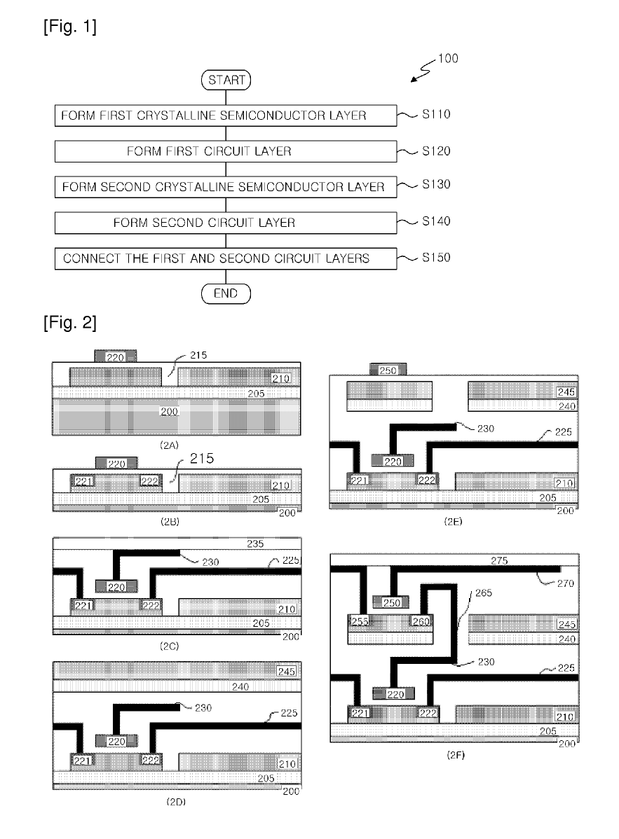

FIG. 1 is a flowchart of a method of manufacturing an integrated circuit having a stacked structure according to an embodiment of the present invention. FIG. 2 is a view illustrating a manufacturing process according to the method illustrated in FIG. 1.

The method of manufacturing the integrated circuit having the stacked structure illustrated in FIG. 1 is described with reference to FIG. 2.

Referring to FIG. 1, the method 100 of manufacturing the integrated circuit having the stacked structure according to an embodiment of the present invention includes: a step S110 of forming a first crystalline semiconductor layer; a step S120 of forming a first circuit layer; a step S130 of forming a second crystalline semiconductor layer; a step S140 of forming a second circuit layer; and a step S150 of connecting the first and second circuit layers.

In the step S110 of forming the first crystalline semiconductor layer, as illustrated in part 2A of FIG. 2, a first buffer layer 205 is formed on a first polycrystalline or amorphous substrate 200, and the first crystalline semiconductor layer 210 is formed thereon.

In the step S120 of forming the first circuit layer, a flat oxide layer 215 and a gate 220 are formed by performing etching and deposition. Thereafter, as illustrated in part 2B of FIG. 2, a source 221 and a drain 222 are formed by performing ion implantation. Thereafter, as illustrated in part 2C of FIG. 2, a first metal layer 225 and a second metal layer 230 are formed by using a general metal process, and a planarized layer 235 that is an oxide layer is formed on the first and second metal layers 225 and 230.

In the step S130 of forming the second crystalline semiconductor layer, as illustrated in part 2D of FIG. 2, a second buffer layer 240 and the second crystalline semiconductor layer 245 are formed on the planarized layer.

In the step S140 of forming the second circuit layer, as illustrated in part 2E of FIG. 2, a flat oxide layer and a gate 250 are formed by performing etching, oxide deposition, poly deposition, and the like. Thereafter, as illustrated in part 2F of FIG. 2, similar to the step S120 of forming the first circuit layer, a source 255 and a drain 260 are formed by performing ion implantation, and first and second metal layers 270 are formed by performing a general metal process.

In the step S150 of connecting the first and second circuit layers, the first and second circuit layers may be connected via a via metal 265.

Thereafter, the step S130 of forming the second crystalline semiconductor layer to the step S150 of connecting the first and second circuit layers are repeated to form a third crystalline semiconductor layer, and the aforementioned method is continuously applied to manufacture the integrated circuit having the stacked structure.

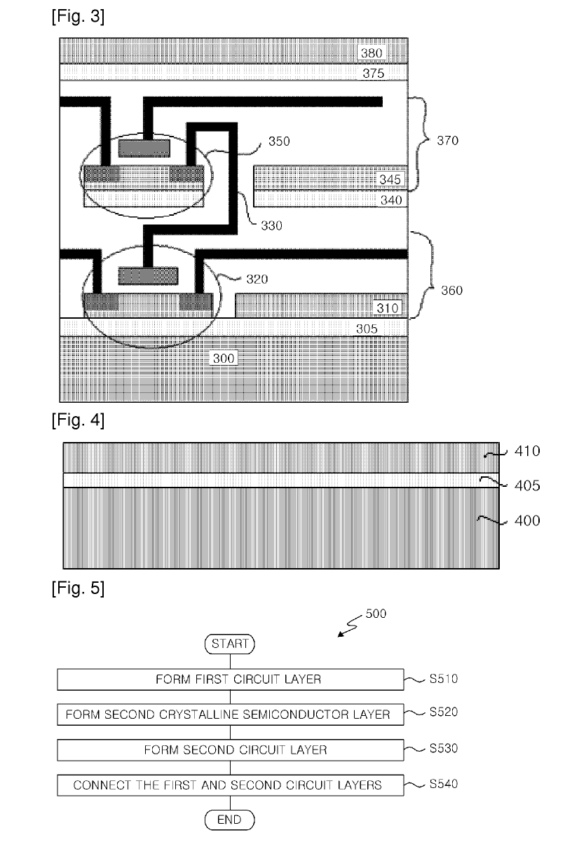

FIG. 3 is a view illustrating the integrated circuit having the stacked structure manufactured by using the method illustrated in FIG. 1.

Referring to FIG. 3, by using the aforementioned method, a first buffer layer 305 and a first crystalline semiconductor layer 310 are formed on a polycrystalline or amorphous substrate 300. A first circuit layer 360 including a first transistor 320 is formed on the first crystalline semiconductor layer 310 by performing a general semiconductor manufacturing process including trench forming, surface oxidation and polygate forming, ion implantation, metal line forming, photolithography, and etching. By performing the same process, a second buffer layer 340 and a second crystalline semiconductor layer 345 are formed, and a second circuit layer 370 including a second transistor 350 is formed. Thereafter, in order to form a third circuit layer, a third buffer layer 375 and a third crystalline semiconductor layer 380 are formed thereon.

In this case, in order to electrically connect the first and second circuit layers 360 and 370, a via metal 330 may be used.

FIG. 4 is a view illustrating a crystalline semiconductor layer used as the substrate in the method of manufacturing the integrated circuit having the stacked structure according to the embodiment of the present invention. The crystalline semiconductor layer includes a polycrystalline or amorphous substrate 400, a buffer layer 405 constructed with a nucleation layer, a seed layer, or a diffusion barrier, and a crystalline semiconductor layer 410. Here, the crystalline semiconductor layer has a defect degree much smaller than that of a polycrystalline or amorphous semiconductor substrate, so that the crystalline semiconductor is very similar to a monocrystalline substrate.

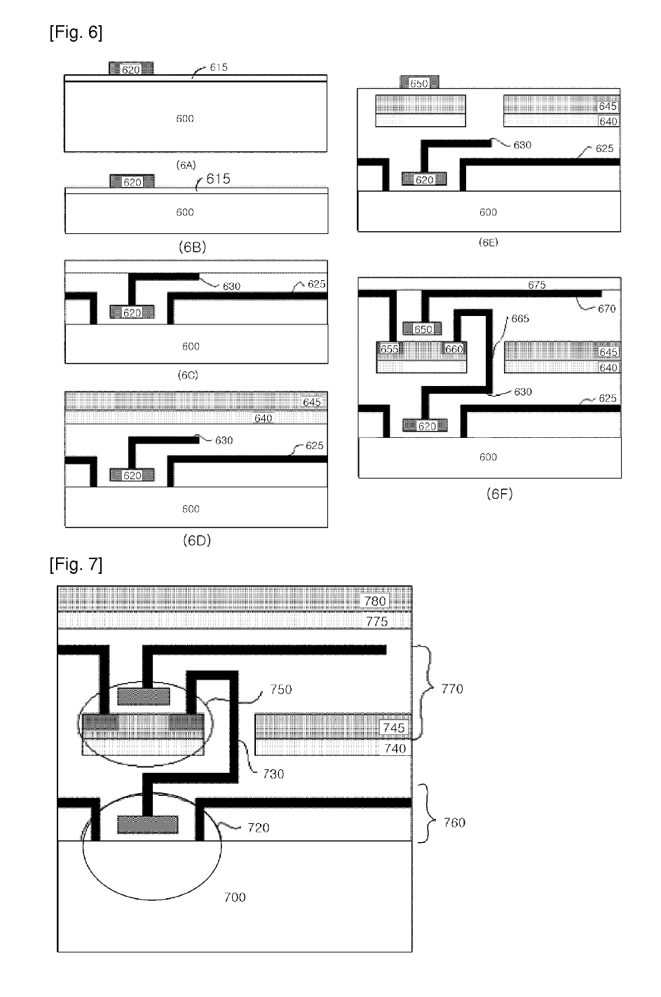

FIG. 5 is a flowchart of a method of manufacturing an integrated circuit having a stacked structure according to another embodiment of the present invention. FIG. 6 is a view illustrating a manufacturing process according to the method illustrated in FIG. 5.

The method of manufacturing the integrated circuit having the stacked structure illustrated in FIG. 5 is described with reference to FIG. 6.

Referring to FIG. 5, the method 500 of manufacturing the integrated circuit having the stacked structure according to the embodiment of the present invention includes: a step S510 of forming a first circuit layer; a step S520 of forming a second crystalline semiconductor layer; a step S530 of forming a second circuit layer; and a step S540 of connecting the first and second circuit layers.

In the method 500 of manufacturing the integrated circuit having the stacked structure illustrated in FIG. 5 according to the embodiment of the present invention, a crystalline semiconductor substrate 600 illustrated in FIG. 6 is used as an initial substrate. Therefore, the step S110 of forming the first crystalline semiconductor layer illustrated in FIG. 1 is not required, and the first circuit layer is formed on the first crystalline semiconductor layer 600 (step S510).

The next steps including the step S520 of forming the second crystalline semiconductor layer, the step S530 of forming the second circuit layer, and the step S540 of connecting the first and second circuit layers are performed by using the same method as that illustrated in FIGS. 1 and 2 to manufacture the integrated circuit having the stacked structure as illustrated in FIGS. 5 and 6.

FIG. 7 is a view illustrating the integrated circuit having the stacked structure manufactured by using the method illustrated in FIG. 5.

Referring to FIG. 7, except that the first crystalline semiconductor substrate 700 is used as the initial substrate, the integrated circuit illustrated in FIG. 7 has the same structure as that of the integrated circuit having the stacked structure illustrated in FIG. 3.

As described above, the thin film stacking method of forming and stacking circuits on crystalline semiconductor thin films can be easily applied to multilayered circuits. In addition, in the thin film stacking method, the entire surface of each circuit layer is joined with an upper or lower circuit layer, so that the method has advantages in terms of heat release as compared with an existing multi-chip packing method in packaging levels or a wafer stacking method in device levels. In addition, in the thin film stacking method, wafer thinning and aligning operations are not needed, so that the manufacturing process is simple. In addition, since the same steps are repeated to form the multilayered circuits, an additional apparatus is not needed.

While the present invention has been particularly shown and described with reference to exemplary embodiments thereof, it will be understood by those skilled in the art that various changes in form and details may be made therein without departing from the spirit and scope of the present invention as defined by the appended claims.

1. A method of manufacturing an integrated circuit having a stacked structure, comprising steps of:
(a) forming a first buffer layer and a first crystalline semiconductor layer on a first substrate;
(b) forming a first circuit layer on the first crystalline semiconductor layer;
(c) forming a second buffer layer and a second crystalline semiconductor layer on the first circuit layer;
(d) forming a second circuit layer on the second crystalline semiconductor layer; and
(e) electrically connecting the first and second circuit layers,
wherein
the first substrate is a substrate having an amorphous structure or a substrate having a polycrystalline structure; and
each of the first and second buffer layers is constructed with a seed layer.

2. The method of claim 1, wherein the steps (c) to (e) are repeated.

3. The method of claim 1, wherein the step (b) comprises:
(b1) forming a flat oxide layer and a gate by performing etching and deposition;
(b2) forming a source and a drain by performing ion implantation;
(b3) forming a first metal layer connected to the source and the drain and a second metal layer connected to the gate by performing a metal process; and
(b4) forming a planarized layer on the first and the second metal layers.

4. The method of claim 1, wherein in the step (e), the first and second circuit layers are connected via a metal.

5. An integrated circuit having a stacked structure manufactured by using the method of manufacturing an integrated circuit having a stacked structure of claim 1.

6. The method of claim 2, wherein the step (b) comprises:
(b1) forming a flat oxide layer and a gate by performing etching and deposition;
(b2) forming a source and a drain by performing ion implantation;
(b3) forming a first metal layer connected to the source and the drain and a second metal layer connected to the gate by performing a metal process; and
(b4) forming a planarized layer on the first and the second metal layers.

7. The method of claim 2, wherein in the step (e), the first and second circuit layers are connected via a metal.
